(19) United States
(12) Patent Application Publication
(10) Pub. No.: US 2016/0255734 A1
(43) Pub. Date: Sep. 1, 2016

(54) APPARATUS FOR REMOVABLY SECURING A PERSONAL ELECTRONIC DEVICE

(71) Applicant: Karen Otabachi, Charlotte, NC (US)

(72) Inventor: Karen Otabachi, Charlotte, NC (US)

(21) Appl. No.: 15/054,306

(22) Filed: Feb. 26, 2016

Related U.S. Application Data
(60) Provisional application No. 62/176,660, filed on Feb. 26, 2015.

(51) Int. Cl. H05K 5/02; F16B 47/00; F16M 13/02; F16B 1/00

(52) U.S. Cl. CPC H05K 5/0204; F16B 1/00; F16B 47/003; F16M 13/02; F16B 2001/0035

(57) ABSTRACT

Disclosed is an apparatus for removably securing a personal electronic device, including a first flexible member having an adhesive side and a magnetic side, the adhesive side coated with a pressure-sensitive adhesive and the magnetic side having at least one permanent magnet or a plurality of spaced permanent magnets attached thereto, the adhesive side adapted to adhere to a non-magnetic surface; and a second flexible member having an adhesive side and a magnetic side, the adhesive side coated with a pressure-sensitive adhesive and the magnetic side having at least one permanent magnet or a plurality of spaced permanent magnets attached thereto, the adhesive side adapted to adhere to a personal electronic device or a cover of a personal electronic device. In certain aspects, the first and second flexible members have a corresponding number of permanent magnets, and the permanent magnets of the first flexible member are magnetized to attract the permanent magnets of the second flexible member.

### CROSS-REFERENCE TO RELATED APPLICATION

This application claims priority to U.S. Provisional Patent Application No. 62/176,660 filed on Feb. 26, 2015, the contents of which are incorporated by reference herein.

### BACKGROUND

Personal electronic devices are readily portable, but these readily portable devices are often placed in high pedestrian traffic areas such as on countertops, dinner tables, and coffee tables that render these devices susceptible to mishandling and damage associated therewith. Often these personal electronic devices are inadvertently damaged due to accidental contact knocking these devices from the surfaces on which they were placed.

### BRIEF SUMMARY

Therefore, a need exists to provide an apparatus that is easily attachable to these personal electronic devices that efficiently prevents and/or reduces mishandling and further prevents and/or reduces subsequent damage to these devices due to mishandling. Disclosed is an apparatus that addresses these needs by potentially preventing and/or reducing mishandling of these personal electronic devices while concurrently allowing quick, easy, and efficient removable attachment of the personal device to, for example, a wall, a car dash, a refrigerator via a pair of flexible members adapted for removable attachment relative to one another. In certain aspects, one of these flexible members may be attached/adhered to a mounting device, a wall, a car dash, a refrigerator, etc., and the other flexible member may be attached to the personal electronic device. Specifically disclosed is an apparatus for removably securing a personal electronic device, including a first flexible member having an adhesive side and a magnetic side, the adhesive side coated with a pressure-sensitive adhesive and the magnetic side having at least one permanent magnet or a plurality of spaced permanent magnets attached thereto, the adhesive side adapted to adhere to a non-magnetic surface; and a second flexible member having an adhesive side and a magnetic side, the adhesive side coated with a pressure-sensitive adhesive and the magnetic side having at least one permanent magnet or a plurality of spaced permanent magnets attached thereto, the adhesive side adapted to adhere to a personal electronic device or a cover of a personal electronic device, wherein: the first and second flexible members have a corresponding number of permanent magnets, and the permanent magnets of the first flexible member are magnetized to attract the permanent magnets of the second flexible member.

In certain aspects, the first and second flexible members each have a corresponding number of spaced permanent magnets adapted for alignment and magnetic attraction when the first flexible member and second flexible member contact each.

In certain aspects, the first and second flexible members each further include a foam layer (i) covering the at least one permanent magnet and/or spaced permanent magnets and (ii) having adhesive coated on one side of each foam layer thereby forming the adhesive side of the first and second flexible members. The foam layer may include and/or be made from a resilient foam thereby forming a resilient foam layer. In certain aspects, the outer surface(s) of the resilient foam layer of the first and second flexible members each have a decorative pattern including for example, a striped pattern, an animal print, a plaid pattern, or other desired aesthetically pleasing patterns.

In certain aspects, the at least one permanent magnet and/or the spaced permanent magnets of the first and second flexible members are positioned in the resilient foam layer such that each of the spaced permanent magnets is recessed inward relative to and directly adjacent to a peripheral edge of the first or second flexible member.

In certain aspects, the resilient foam layer of the first and second flexible members is a reticulated foam, a partially reticulated foam, or a closed cell foam.

In certain aspects, the resilient foam layer of the first and second flexible members is either a partially reticulated foam or a closed cell foam, the partially reticulated foam or a closed cell foam formed of ethylene vinyl acetate copolymer.

In certain aspects, the resilient foam layer of the first and second flexible members is a closed cell foam comprising ethylene vinyl acetate copolymer, wherein, for example, the closed cell foam includes at least 99 wt % ethylene vinyl acetate copolymer with the remaining 1 wt % of the foam being fillers, coloring agents, flame retardants, or any combination thereof.

In certain aspects, the first and second flexible members have the same shape.

In certain aspects, the shape of the first and second flexible members is triangular, square, rectangular, or a rectangular shape with curved corners.

In certain aspects, the shape of the first and second flexible members is a rectangular shape with curved corners

Embodiments of the invention can include one or more or any combination of the above features and configurations.

Additional features, aspects and advantages of the invention will be set forth in the detailed description which follows, and in part will be readily apparent to those skilled in the art from that description or recognized by practicing the invention as described herein. It is to be understood that both the foregoing general description and the following detailed description present various embodiments of the invention, and are intended to provide an overview or framework for understanding the nature and character of the invention as it is claimed. The accompanying drawings are included to provide a further understanding of the invention, and are incorporated in and constitute a part of this specification.

### BRIEF DESCRIPTION OF THE DRAWINGS

These and other features, aspects and advantages of the present invention are better understood when the following detailed description of the invention is read with reference to the accompanying drawings, in which:

FIG. 1 is a perspective view of the adhesive side of the first and second flexible members;

FIG. 2 is a perspective view of the magnetic side of the first and second flexible members:

FIG. 3 is an exemplary cross sectional view of the flexible members depicting the adhesive side, magnets, foam layer, and magnetic attraction between the flexible members;

FIGS. 4a and 4b depict various magnet configurations in the flexible member(s); and

FIG. 5 is an environmental view of the first and second flexible members of the disclosed apparatus in use.

### DETAILED DESCRIPTION

The present invention will now be described more fully hereinafter with reference to the accompanying drawings in which exemplary embodiments of the invention are shown. However, the invention may be embodied in many different forms and should not be construed as limited to the representative embodiments set forth herein. The exemplary embodiments are provided so that this disclosure will be both thorough and complete, and will fully convey the scope of the invention and enable one of ordinary skill in the art to make, use and practice the invention. Like reference numbers refer to like elements throughout the various drawings.

Disclosed is an apparatus that prevents and/or reduces mishandling of personal electronic devices (e.g., smartphones, tablets, iPads, etc.) by allowing quick, easy, and efficient removable attachment of the personal device to, for example, a wall, a car dash, a refrigerator via a pair of flexible members adapted for removable attachment. In certain aspects, one of these flexible members may be attached to a mounting device, a wall, a car dash, a refrigerator, etc., and the other flexible member may be attached to the personal electronic device.

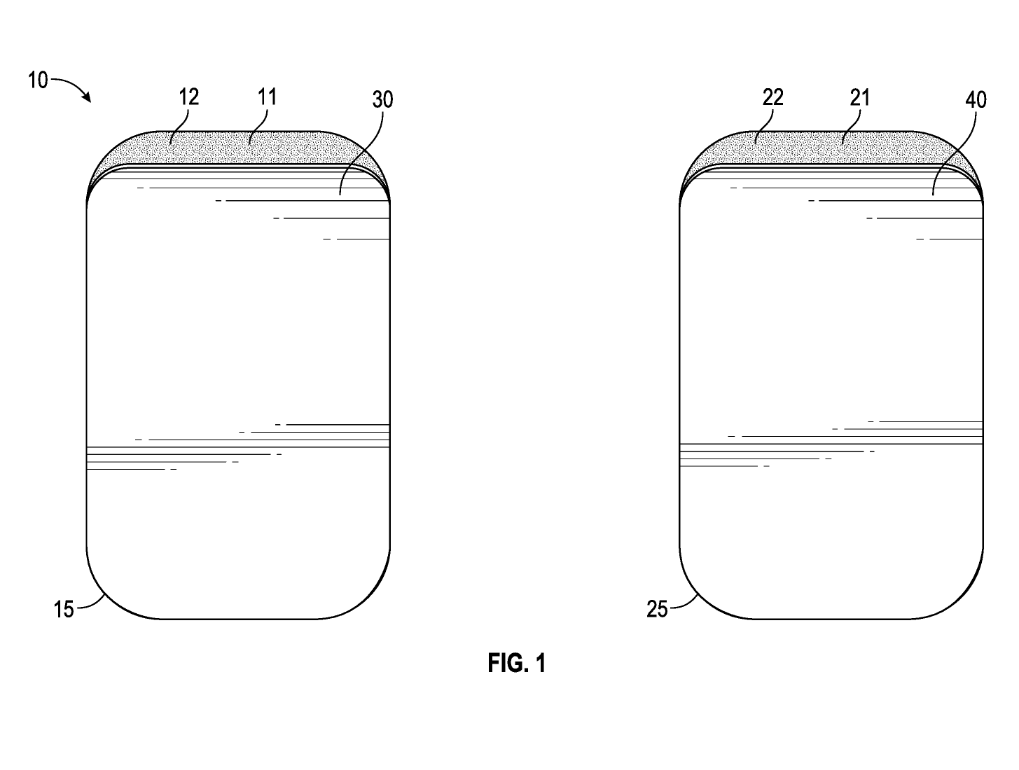

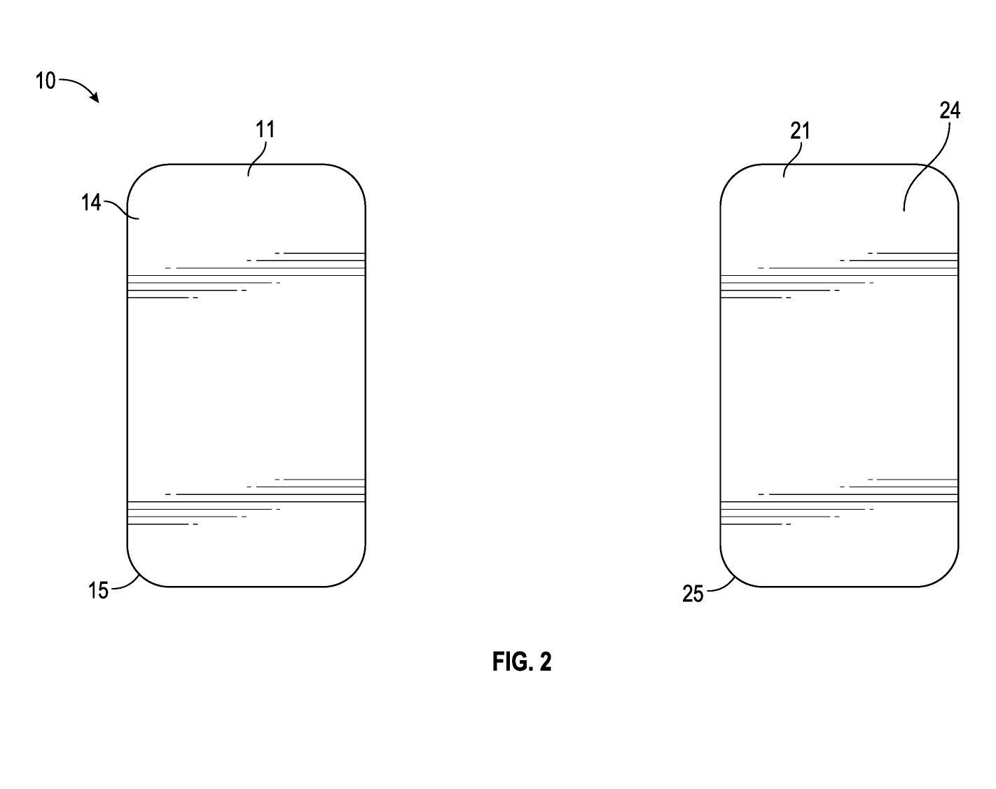

FIGS. 1-4b depict various embodiments of the apparatus for removably securing a personal electronic device 10, 100 disclosed herein. As depicted, for example, in FIGS. 1-4b, the apparatus 10, 100 includes a first flexible member 11 and a second flexible member 21. The first flexible member 11 and second flexible member 21 each have an adhesive side/layer 12, 22 for attaching the flexible members to a personal electronic and/or a desired mounting surface (e.g., mounting device, a wall, a car dash, a refrigerator), a coverslip 30, 40 initially attached to the adhesive layer that is removed when using the apparatus, a magnetic material 13, 23, 113, 223 (a magnetic side or permanent magnets) adapted for removable attachment of the first flexible member to the second flexible member, and a foam layer 14, 24.

As shown in FIG. 1, adhesive layer 12, 22 coats an entire side of the first flexible member 11 and second member 22 respectively, and once coverslip 30, 40 is removed therefrom, the adhesive layer 12, 22 allows the flexible member to be securely attached/adhered to a desired surface (e.g., a personal electronic device, mounting device, a wall, a car dash, a refrigerator). In certain aspects, the adhesive is a pressure sensitive adhesive having an elastomer compounded with a suitable tackifier. For example, these pressure sensitive adhesives may include acrylic/acrylate based, butyl rubber based, ethylene-vinyl acetate based, natural rubber based, styrene based (e.g., styrene block copolymers, styrene-butadiene-styrene, styrene-ethylene/butylene-styrene (SEBS), styrene-ethylene/propylene (SEP), or styrene-isoprene-styrene (SIS)), or silicone rubber based pressure sensitive adhesives. These pressure sensitive adhesives preferably have long lifespans ranging from six months to 3 years, 1 year to 3 years, 2 years to 3 years, thus allowing for durability and operability of the disclosed apparatus 10, 100 throughout the above mentioned time periods.

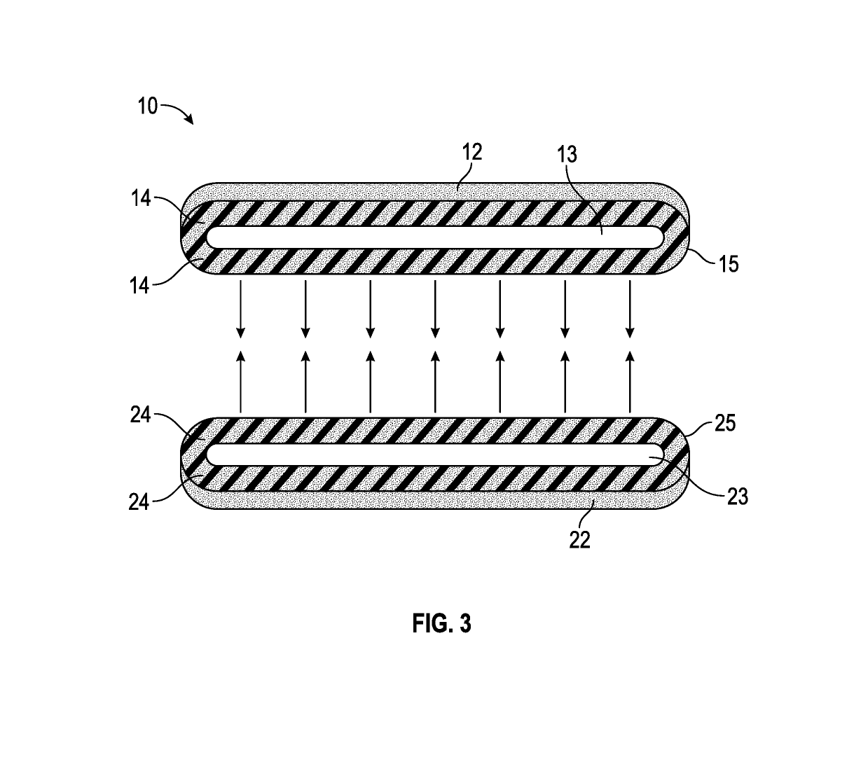

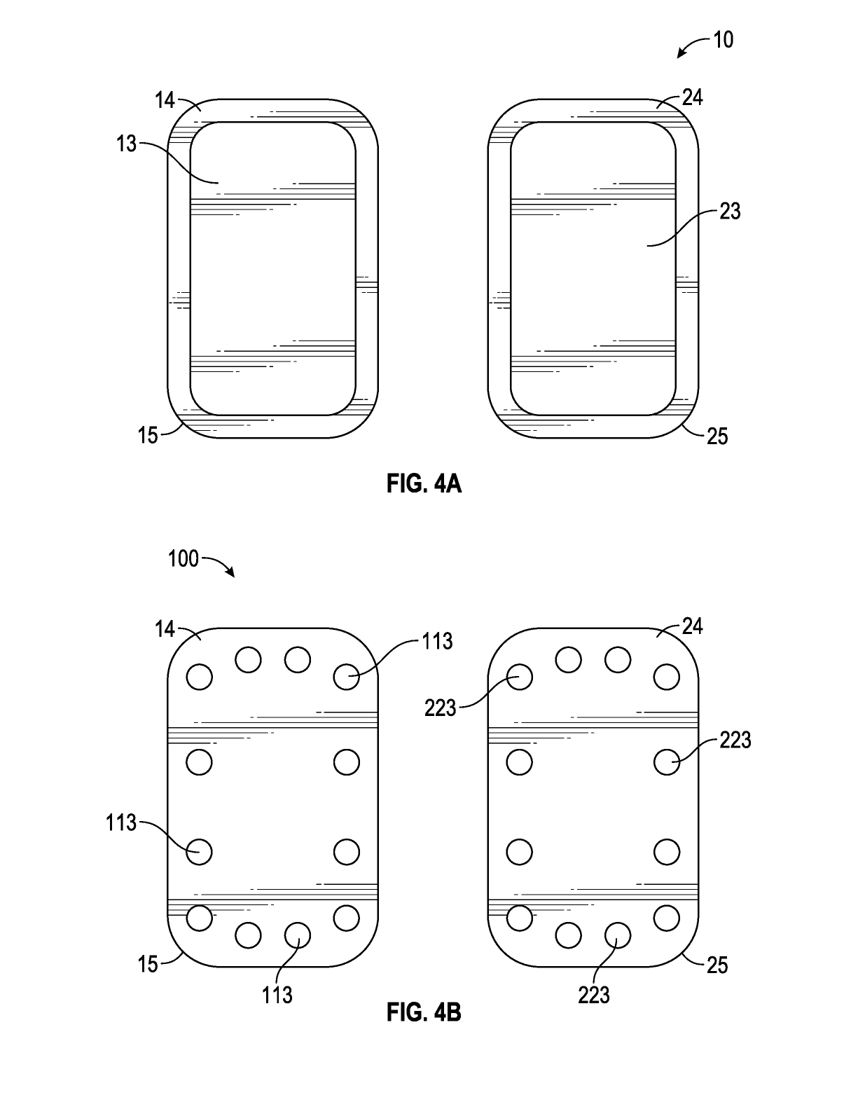

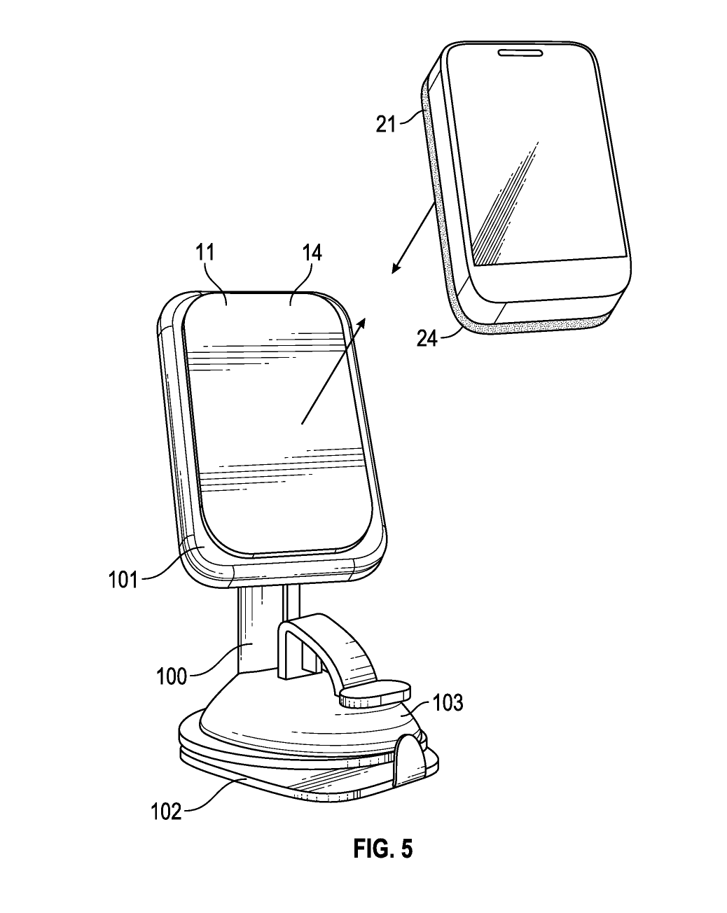

As further shown in FIGS. 1-4b, the first flexible member 11 and second flexible member 21 each comprise a foam layer 14, 24 covering the magnetic material 13, 23, 113, 223. For example, in one embodiment as depicted in FIGS. 3 and 4a, the magnetic material 13, 23 is a permanent magnet including a flexible, continuous sheet embedded within the foam layer 14, 24. However, in another embodiment and as depicted in FIG. 4b, the magnetic material 113, 223 are a plurality of spaced apart permanent magnets embedded within the foam layer 14, 24. In certain aspects, magnetic material 13, 23, 113, 223 are positioned in the foam layer 14, 24 such that each of the magnetic material (e.g., the flexible continuous sheet and/or the plurality of spaced apart permanent magnets) is recessed relative to and directly adjacent to a peripheral edge 15, 25 of the first flexible 11 and second flexible member 21. By having the magnetic material recessed relative to but directly adjacent to the peripheral edge 15, 25, this feature provides an aesthetically pleasing appearance to a user because the magnetic material is embedded within the foam layer 14, 24 and not readily viewable. However, by having the magnetic material adjacent to the peripheral edge 15, 25, this positioning ensures the strongest possible attachment between the first and second flexible members when, for example, removably securing the first flexible member to the second flexible member as shown in FIGS. 3 and 5.

In certain aspects, the foam layer 14, 24 is a resilient foam layer including a reticulated foam, a partially reticulated foam, or a closed cell foam. In certain aspects, this foam is formed from an organic copolymer, and the organic copolymer includes ethylene vinyl acetate copolymer. In certain aspects, the foam layer 14, 24 is a resilient foam layer comprising a closed cell foam formed of ethylene vinyl acetate copolymer, wherein, for example, the closed cell foam includes at least 99 wt % ethylene vinyl acetate copolymer with the remaining 1 wt % being fillers, coloring agents, flame retardants (e.g., carbon black), or any combination thereof. Either while polymerizing the foam layer 14, 24 or after polymerization, a decorative pattern may be include on an outer surface of the foam layer. This decorative pattern may include a striped pattern, an animal print, a plaid pattern, or other desired aesthetically pleasing patterns.

FIG. 3 depicts attractive magnetic forces (arrows) between magnetic material 13 of the first flexible member 11 and magnetic material 23 of the second flexible member 21, which allow for removably securing the second flexible member (attached to a personal electronic device) when brought in close proximity to the first flexible member.

FIG. 5 depicts an environmental view of the first and second flexible members in use. Specifically, the adhesive side of first flexible member 11 is adhered to a platform 101 on mount member 100, and the adhesive side of second flexible member 21 is adhered to, for example, a cellular phone. Mount member 100 may be secured to a desired surface via securing members 102, 103. When the apparatus user desires to removably secure the cellular phone to the mount member 100, the user places the second flexible member 21 (adhered to the cellular phone) on the first flexible member 11 and the attractive magnetic forces between magnetic material 13, 23, 113, 223 attach the first and second flexible members to one another thereby removably securing the cellular phone to the platform 101.

In certain aspects, the first and second flexible members have the same shape. The shape of the first and second flexible members is triangular, square, rectangular, or a rectangular shape with curved corners. In certain aspects, the shape of the first and second flexible members is a rectangular shape with curved corners

The above disclosed apparatus 10, 100 allows for easy and secure attachment of personal electronic devices to a desired surface while concurrently preventing and/or reducing mishandling of and/or damaging these devices while not in use.

The foregoing description provides embodiments of the invention by way of example only. It is envisioned that other embodiments may perform similar functions and/or achieve similar results. Any and all such equivalent embodiments and examples are within the scope of the present invention and are intended to be covered by the appended claims.

What is claimed is:

1. An apparatus for removably securing a personal electronic device, comprising:
a first flexible member having an adhesive side and a magnetic side, the adhesive side coated with a pressure-sensitive adhesive and the magnetic side having at least a permanent magnet attached thereto, the adhesive side adapted to adhere to a non-magnetic surface; and
a second flexible member having an adhesive side and a magnetic side, the adhesive side coated with a pressure-sensitive adhesive and the magnetic side having at least a permanent magnets attached thereto, the adhesive side adapted to adhere to a personal electronic device or a cover of a personal electronic device, wherein:
the permanent magnet of the first flexible member is magnetized to attract the permanent magnet of the second flexible member.

2. The apparatus of claim 1, wherein the first and second flexible members each have a corresponding number of spaced permanent magnets adapted for alignment when the first flexible member and second flexible member contact each.

3. The apparatus of claim 2, wherein the first and second flexible members each further comprise a resilient foam layer covering the spaced permanent magnets and having adhesive coated on one side of each resilient foam layer to for the adhesive side of the first and second flexible members.

4. The apparatus of claim 3, wherein the spaced permanent magnets of the first and second flexible members are positioned in the resilient foam layer such that each of the spaced permanent magnets is recessed relative to and directly adjacent to a peripheral edge of the first or second flexible member.

5. The apparatus of claim 4, wherein the first and second flexible members have the same shape.

6. The apparatus of claim 4, wherein the shape of the first and second flexible members is triangular, square, rectangular, or a rectangular shape with curved corners.

7. The apparatus of claim 4, wherein the shape of the first and second flexible members is a rectangular shape with curved corners

8. The apparatus of claim 7, wherein the resilient foam layer of the first and second flexible members is a reticulated foam, a partially reticulated foam, or a closed cell foam.

9. The apparatus of claim 7, wherein the resilient foam layer of the first and second flexible members is either a partially reticulated foam or a closed cell foam, the partially reticulated foam or a closed cell foam comprising ethylene vinyl acetate copolymer.

10. The apparatus of claim 7, wherein the resilient foam layer of the first and second flexible members is a closed cell foam comprising ethylene vinyl acetate copolymer.

11. The apparatus of claim 9, wherein the partially reticulated foam or a closed cell foam comprises at least 99 wt % ethylene vinyl acetate copolymer.

12. The apparatus of claim 10, wherein the partially reticulated foam or a closed cell foam comprises at least 99 wt % ethylene vinyl acetate copolymer.

13. The apparatus of claim 12, wherein an outer surface of the resilient foam layer of the first and second flexible members each have a decorative pattern.

14. An apparatus for removably securing a personal electronic device, comprising:
a first flexible member having an adhesive side and a magnetic side, the adhesive side coated with a pressure-sensitive adhesive and the magnetic side having a plurality of spaced permanent magnets attached thereto, the adhesive side adapted to adhere to a non-magnetic surface; and
a second flexible member having an adhesive side and a magnetic side, the adhesive side coated with a pressure-sensitive adhesive and the magnetic side having a plurality of spaced permanent magnets attached thereto, the adhesive side adapted to adhere to a personal electronic device or a cover of a personal electronic device, wherein:
the first and second flexible members have a corresponding number of spaced permanent magnets with each of the spaced permanent magnets being laterally adjacent to and inwardly offset relative to a peripheral edge of the first and second flexible members, and
the spaced permanent magnets of the first flexible member are magnetized to attract the spaced permanent magnets of the second flexible member.

15. The apparatus of claim 14, wherein the first and second flexible members each further comprise a resilient foam layer covering the spaced permanent magnets and having adhesive coated on one side of each resilient foam layer to for the adhesive side of the first and second flexible members in which the resilient foam layer is a closed cell foam comprising 99 wt % ethylene vinyl acetate copolymer.
